(19) United States
(12) Patent Application Publication
(10) Pub. No.: US 2026/0344438 A1
(43) Pub. Date: Oct. 29, 2026

(54) SEMICONDUCTOR DEVICE HAVING A GUARD RING STRUCTURE

(71) Applicant: SK hynix Inc., Gyeonggi-do (KR)

(72) Inventor: Heon Yong CHANG, Gyeonggi-do (KR)

(21) Appl. No.: 19/318,391

(22) Filed: Sep. 4, 2025

(30) Foreign Application Priority Data
Jan. 22, 2025 (KR) 10-2025-0009243

(51) Int. Cl. H10W 42/00; H10B 12/00; H10D 64/27; H10W 10/17; H10W 20/41; H10W 46/00

(52) U.S. Cl. CPC H10W 42/121; H10W 10/17; H10W 20/435; H10W 46/201; H10B 12/315; H10B 12/34; H10B 12/50; H10D 64/513; H10D 64/516; H10D 64/518

(57) ABSTRACT

A semiconductor device includes a substrate having a chip area and a guard ring area, the guard ring area surrounding the chip area; a guard ring structure and a crack detection circuit structure which are disposed over the substrate in the guard ring area; a crack detection pad structure disposed over the substrate in the chip area; and a crack detection pad connection part buried in the substrate to electrically connect the crack detection circuit structure to the crack detection pad structure across a portion of the guard ring structure. The crack detection pad connection part includes a crack detection pad connection buried electrode and a crack detection pad connection buried capping layer which is disposed over the crack detection pad connection buried electrode.

### CROSS-REFERENCE TO RELATED APPLICATIONS

This patent document claims priority under 35 U.S.C. 119(a) to Korean Patent Application No. 10-2025-0009243, filed on Jan. 22, 2025, which is incorporated herein by reference in its entirety.

### TECHNICAL FIELD

Embodiments of the present disclosure relate to a semiconductor device, and more particularly, to a semiconductor device having a guard ring structure.

### BACKGROUND

A guard ring structure in semiconductor devices is a design feature used to provide blocking crack propagation and humidity penetration. As semiconductor chips become thinner, the importance of maintaining structural stability and physical robustness of the guard ring structure increases.

### SUMMARY

An embodiment of the present disclosure provides a guard ring structure configured to maintain structural stability and physical robustness of a semiconductor device.

An embodiment of the present disclosure provides pad structures of a test circuit and a crack detection circuit disposed in a chip area.

An embodiment of the present disclosure provides connecting a test circuit and a crack detection circuit to pad structures without structural and physical loss of the guard ring structure.

In accordance with an embodiment of the present disclosure, a semiconductor device includes a substrate having a chip area and a guard ring area which is disposed to surround the chip area; a guard ring structure and a crack detection circuit structure which are disposed over the substrate in the guard ring area; a crack detection pad structure disposed over the substrate in the chip area; and a crack detection pad connection part buried in the substrate to electrically connect the crack detection circuit structure to the crack detection pad structure across a portion of the guard ring structure. The crack detection pad connection part includes a crack detection pad connection buried electrode and a crack detection pad connection buried capping layer which is disposed over the crack detection pad connection buried electrode.

In accordance with an embodiment of the present disclosure, a semiconductor device includes a substrate having a chip area and a guard ring area defined by scribe lanes, the guard ring area being disposed to surround the chip area; a guard ring structure disposed over the substrate in the guard ring area; a test circuit structure disposed over the substrate in at least one of the scribe lanes; a test pad structure disposed over the substrate in the chip area; and a test pad connection part buried in the substrate to electrically connect the test circuit structure to the test pad structure across the guard ring area. The test pad connection part includes a test pad connection buried electrode and a test pad connection buried capping layer which is disposed over the test pad connection buried electrode.

In accordance with an embodiment of the present disclosure, a semiconductor device includes a substrate having a chip area and a guard ring area defined by scribe lanes, the guard ring area being disposed to surround the chip area; a guard ring structure disposed over the substrate in the guard ring area; a circuit structure disposed over the substrate in at least one of the scribe lanes or the guard ring area; a pad structure disposed over the substrate in the chip area; a pad connection part electrically connecting the circuit structure to the pad structure across the guard ring structure; and a cell structure disposed in the chip area. The pad connection part includes a pad connection buried electrode buried in the substrate, and a pad connection buried capping layer disposed over the pad connection buried electrode. The cell structure includes a cell isolation region in the substrate to define a cell active region, and a buried gate line buried in the substrate. The buried gate line includes a buried gate electrode, and a buried gate capping layer disposed over the buried gate electrode. The pad connection buried electrode and the buried gate electrode are disposed at a same level. The pad connection buried capping layer and the buried gate capping layer are disposed at a same level.

These and other features and advantages of the embodiments of the present disclosure will become apparent to those skilled in the art from the following detailed description in conjunction with the following drawings.

### BRIEF DESCRIPTION OF THE DRAWINGS

FIG. 1A is a view illustrating a wafer according to an embodiment of the present disclosure, and FIG. 1B is an enlarged view of the area A of FIG. 1A.

FIGS. 2A to 2C are enlarged views schematically illustrating portions of a guard ring area and a chip area shown in FIG. 1B.

FIGS. 3A to 3D are top views illustrating a portion of a scribe lane, a portion of a guard ring area, a portion of a cell area in a chip area, and a portion of a peripheral circuit area in the chip area of a semiconductor device.

FIGS. 4 to 7 are longitudinal cross-sectional views schematically illustrating a semiconductor device according to an embodiment of the present disclosure.

FIG. 8A is a longitudinal sectional view taken along the line I-I′ of FIG. 3A, and FIG. 8B is a longitudinal sectional view taken along the line V-V′ of FIG. 3A.

FIG. 9 is a longitudinal sectional view taken along the lines VI-VI′ of FIG. 3A or VII-VII′ of FIG. 3B.

FIG. 10 is a longitudinal sectional view taken along the line VIII-VIII′ of FIG. 3B.

FIGS. 11A to 11D are longitudinal cross-sectional views taken along the line IX-IX′ of FIG. 3B.

### DETAILED DESCRIPTION

Embodiments of the present disclosure are described in detail with reference to the accompanying drawings. Specific structural or functional descriptions of specific embodiments are provided as examples to describe the technical concepts that are disclosed in the present application. However, it should be understood that various other examples or embodiments in accordance with the technical concepts of the present disclosure may be carried out in various forms by those with ordinary skill in the art without departing from the scope of the present disclosure. Hence, the present invention is not limited only to the described examples or embodiments.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

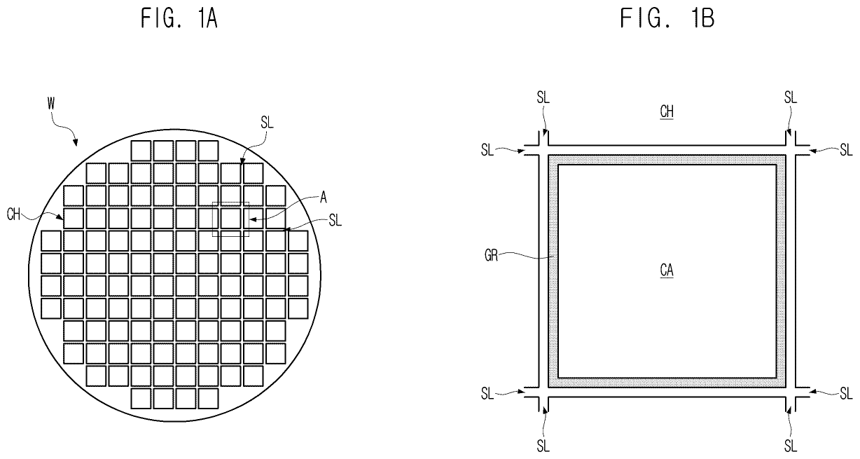

FIG. 1A is a view illustrating a wafer W according to an embodiment of the present disclosure, and FIG. 1B is an enlarged view of the area A of FIG. 1A. Referring to FIGS. 1A and 1B, the wafer W may include a plurality of semiconductor chips CH arranged in a matrix form. A plurality of semiconductor chips CH may be separated by scribe lanes SL arranged in a lattice form. Each of the semiconductor chips CH may include a chip area CA and a guard ring area GR. The chip area CA may include a cell area and a peripheral circuit area. Memory cells may be disposed in the cell area, and peripheral circuits may be disposed in the peripheral circuit area. The guard ring area GR may be disposed adjacent to the scribe lanes SL to surround the chip area CA.

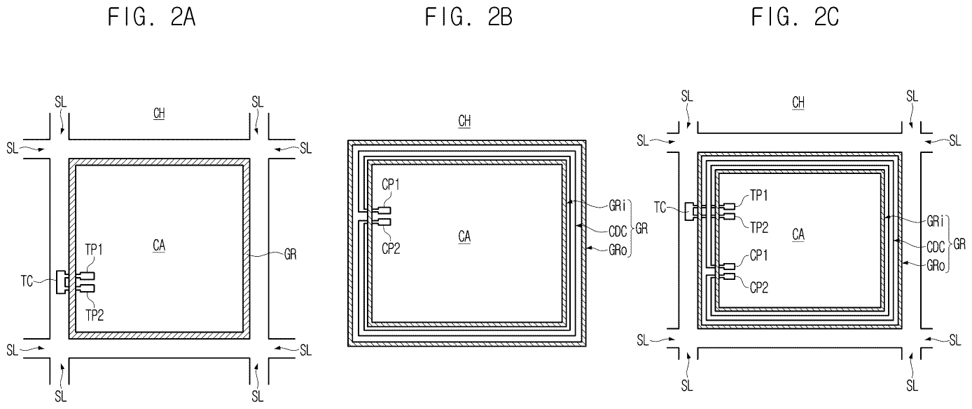

FIGS. 2A to 2C are enlarged views illustrating the guard ring area and a portion of the chip area of FIG. 1B. Referring to FIG. 2A, the semiconductor chip CH may include the chip area CA and the guard ring area GR defined by the scribe lanes SL. The guard ring area GR may surround the chip area CA. The semiconductor chip CH may further include a test circuit TC disposed in the scribe lane SL, and a first test pad TP1 and a second test pad TP2 disposed in the chip area CA. Each of the first test pad TP1 and the second test pad TP2 may be electrically connected to the test circuit TC. For example, the first test pad TP1 and the second test pad TP2 may correspond to parts of the test circuit TC, e.g., a first terminal and a second terminal, respectively. Accordingly, a portion of the test circuit TC may cross the guard ring area GR.

Referring to FIG. 2B, the semiconductor chip CH may include an inner guard ring GRi, an outer guard ring GRo, and a crack detection circuit CDC disposed in the guard ring area GR, and may include a first crack detection pad CP1 and a second crack detection pad CP2 disposed in the chip area CA. The crack detection circuit CDC may be configured to monitor cracks or defects (including hairline, sidewall, inner, or backside cracks) during a manufacturing process for the semiconductor chip CH. The inner guard ring GRi, the outer guard ring GRo, and the crack detection circuit CDC may each have a rectangular frame form in a top view. The crack detection circuit CDC may be disposed between the inner guard ring GRi and the outer guard ring GRo. The first crack detection pad CP1 and the second crack detection pad CP2 may be disposed in the chip area CA. The first crack detection pad CP1 and the second crack detection pad CP2 may be electrically connected to the crack detection circuit CDC. For example, the first crack detection pad CP1 and the second crack detection pad CP2 may correspond to parts of the crack detection circuit CDC, e.g., the first terminal and the second terminal, respectively. Thus, the parts of the crack detection circuit CDC may cross the inner guard ring GRi to be electrically connected to the first and second crack detection pads CP1 and CP2, respectively.

Referring to FIG. 2C, the semiconductor chip CH may include a chip area CA and a guard ring area GR defined by the scribe lanes SL. The guard ring area GR may surround the chip area CA. The semiconductor chip CH may include a test circuit TC disposed in the scribe lane SL, an inner guard ring GRi, an outer guard ring GRo, and a crack detection circuit CDC disposed in the guard ring area GR, and a first crack detection pad CP1, a second crack detection pad CP2, a first test pad TP1, and a second test pad TP2 disposed in the chip area CA. Parts of the crack detection circuit CDC may cross the inner guard ring GRi, and parts of the test circuit TC may cross the inner guard ring GRi, the outer guard ring GRo, and the crack detection circuit CDC.

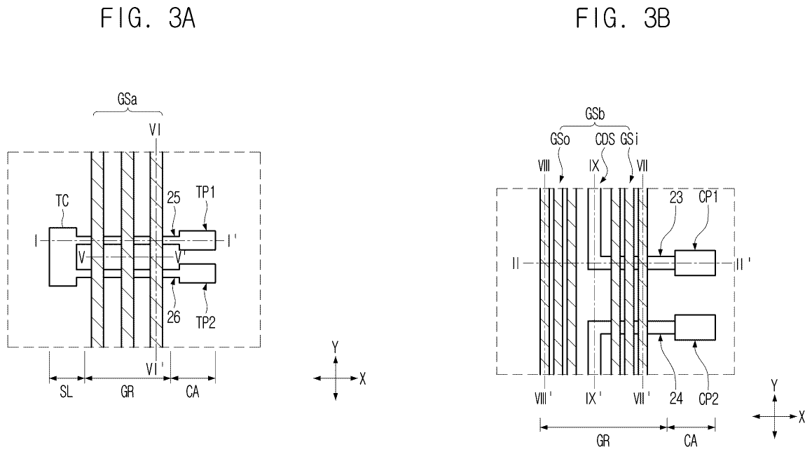

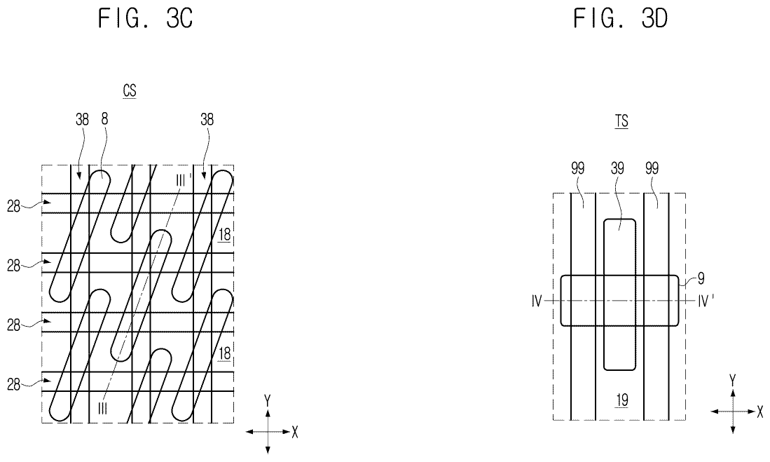

FIGS. 3A to 3D are top views illustrating a portion of a scribe lane SL, a portion of a guard ring area GR, a portion of a cell area in a chip area CA, and a portion of a peripheral circuit area in the chip area CA of a semiconductor device.

Referring to FIG. 3A, the semiconductor device may include a test circuit TC disposed in the scribe lane SL, a guard ring structure GSa, test pads TP1 and TP2 disposed in the chip area CA, and test pad connection parts 25 and 26 disposed in the guard ring area GR. The guard ring structure GSa may include a plurality of guard rings disposed to be spaced apart from each other in a first horizontal direction X and to extend parallel to each other in a second horizontal direction Y. The test pad connection parts 25 and 26 may cross the guard ring structure GSa. The first horizontal direction X and the second horizontal direction Y may be perpendicular to each other.

Referring to FIG. 3B, the semiconductor device may include a guard ring structure GSb disposed in the guard ring area GR, crack detection pads CP1 and CP2 disposed in the chip area CA, and crack detection pad connection parts 23 and 24 crossing a portion of the guard ring area GR and a portion of the chip area CA. The guard ring structure GSb may include an inner guard ring structure GSi, an outer guard ring structure GSo, and a crack detection circuit structure CDS between the inner guard ring structure GSi and the outer guard ring structure GSo disposed to be spaced apart from each other in the first horizontal direction X and to extend parallel in the second horizontal direction Y. The inner guard ring structure GSi and the outer guard ring structure GSo may each include a plurality of guard rings in parallel with each other. The crack detection pad connection parts 23 and 24 may cross the inner guard ring structure GSi.

Referring to FIG. 3C, the semiconductor device may include a cell structure CS in a cell area in a chip area CA. The cell structure CS may include cell active regions 8, buried gate lines 28, and bit lines 38. The cell active regions 8 may be defined by the cell isolation (e.g., shallow trench isolation) region 18. The cell active regions 8 may each have a segment shape elongated in a diagonal direction. The buried gate lines 28 may extend in parallel with each other to cross the cell active regions 8 in the first horizontal direction X. Two of the buried gate lines 28 may cross one of cell active regions 8. The buried gate lines 28 may be cell word lines. Each of the bit lines 38 may extend in parallel with each other to cross a center of each of the cell active regions 8 in the second horizontal direction Y.

Referring to FIG. 3D, the semiconductor device may include a peripheral transistor structure TS in a peripheral circuit area in the chip area CA. The peripheral transistor structure TS may include a peripheral active region 9, a peripheral gate electrode 39, and peripheral interconnection lines 99. The peripheral active region 9 may be defined by the peripheral isolation (e.g., shallow trench isolation, STI) region 19. The peripheral gate electrode 39 may be disposed to cross the peripheral active region 19. The peripheral interconnection lines 99 may each extend in a line form in the second horizontal direction Y to overlap a portion of the peripheral active region 9, respectively.

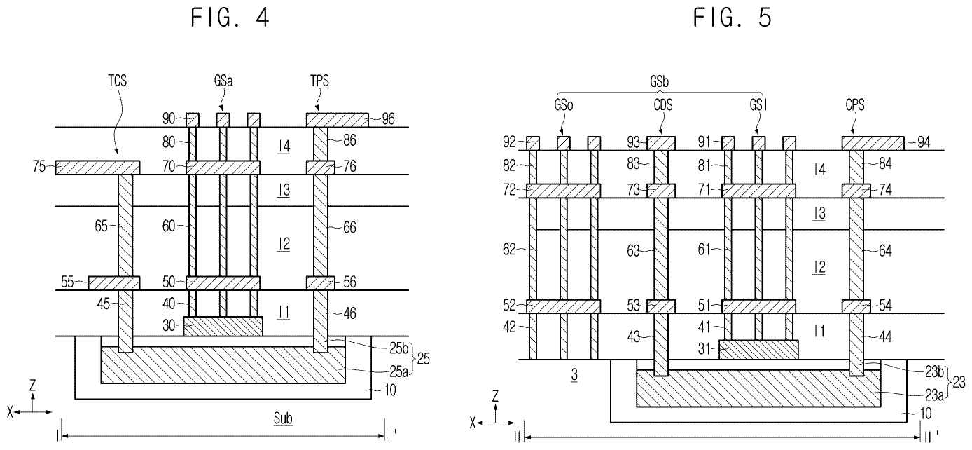

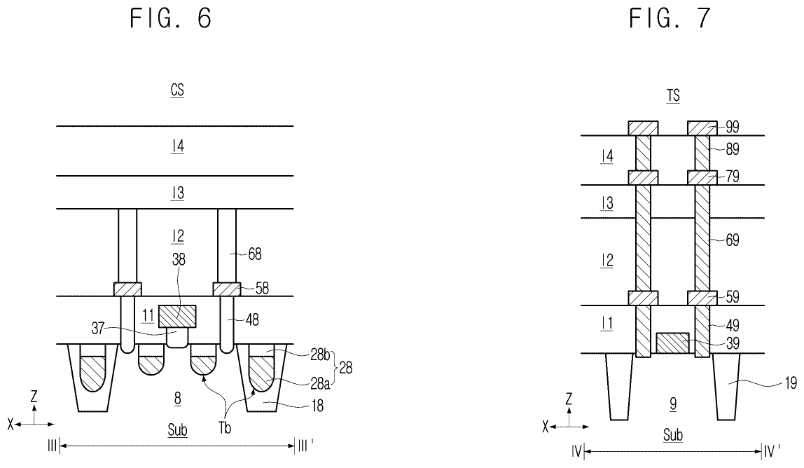

FIGS. 4 to 7 are longitudinal cross-sectional views schematically illustrating a semiconductor device according to an embodiment of the present disclosure. FIG. 4 is a longitudinal sectional view taken along the line I-I′ of FIG. 3A, FIG. 5 is a longitudinal sectional view taken along the line II-II′ of FIG. 3B, FIG. 6 is a longitudinal sectional view taken along the line III-III′ of FIG. 3C, and FIG. 7 is a longitudinal sectional view taken along the line IV-IV′ of FIG. 3D.

Referring to FIG. 4, the semiconductor device may include a guard ring structure GSa, a test circuit structure TCS, a test pad structure TPS, and a test pad connection part 25. The semiconductor device may further include a lower interlayer insulating layer I1, a middle-lower interlayer insulating layer I2, a middle-upper interlayer insulating layer I3, and an upper interlayer insulating layer I4.

In a vertical direction Z, the guard ring structure GSa may include a guard ring lower electrode 30, a guard ring lower plug 40, a guard ring lower pad 50, a guard ring middle plug 60, a guard ring middle pad 70, a guard ring upper plug 80, and a guard ring upper pad 90.

The guard ring lower electrode 30 may be directly disposed on the substrate Sub. The vertical direction Z may be perpendicular to the first horizontal direction X and the second horizontal direction Y. The guard ring lower electrode 30 may be formed directly on a surface of the substrate Sub. The guard ring lower electrode 30 may include an insulating lower layer, a conductive middle layer, and an insulating upper layer. The guard ring lower plug 40 may be disposed on the guard ring lower electrode 30 to vertically pass through the lower interlayer insulating layer I1. The guard ring lower plug 40 may vertically pass through the insulating upper layer of the guard ring lower electrode 30 to be electrically connected to the conductive middle layer of the guard ring lower electrode 30. The guard ring lower pad 50 may be disposed on the guard ring lower plug 40 and the lower interlayer insulating layer I1. The guard ring lower pad 50 may vertically overlap and be electrically connected to the guard ring lower plug 40. The guard ring middle plug 60 may vertically pass through the middle-upper interlayer insulating layer I3 and the middle-lower interlayer insulating layer I2 to vertically overlap and be electrically connected to the guard ring lower pad 50. The guard ring middle pad 70 may be disposed on the guard ring middle plug 60 and the middle-upper interlayer insulating layer I3. The guard ring middle pad 70 may vertically overlap and be electrically connected to the guard ring middle plug 60. The guard ring upper plug 80 may vertically pass through the upper interlayer insulating layer I4 to vertically overlap and be electrically connect to the guard ring middle pad 70. The guard ring upper pad 90 may be disposed on the guard ring upper plug 80 and the upper interlayer insulating layer I4. The guard ring upper pad 90 may vertically overlap and be electrically connected to the guard ring upper plug 80.

The guard ring lower electrode 30, the guard ring lower pad 50, the guard ring middle pad 70, and the guard ring upper pad 90 may each have a line shape extending in the first horizontal direction X or the second horizontal direction Y. The guard ring lower plug 40, the guard ring middle plug 60, and the guard ring upper plug 80 may each have a wall shape extending in the second horizontal direction Y and the vertical direction Z. The guard ring lower electrode 30, the guard ring lower plug 40, the guard ring lower pad 50, the guard ring middle plug 60, the guard ring middle pad 70, the guard ring upper plug 80, and the guard ring upper pad 90 may each include a conductor such as a metal, a metal alloy, or a metal nitride.

The test circuit structure TCS may include a test circuit lower contact plug 45, a test circuit lower contact pad 55, a test circuit upper contact plug 65, and a test circuit upper contact pad 75. The test circuit lower contact plug 45 may vertically pass through the lower interlayer insulating layer I1 to be physically and electrically connected to the test pad connection part 25. The test circuit lower contact pad 55 may be disposed on the test circuit lower contact plug 45 and the lower interlayer insulating layer I1 to vertically overlap and be electrically connected to the test circuit lower contact plug 45. The test circuit upper contact plug 65 may vertically pass through the middle-upper interlayer insulating layer I3 and the middle-lower interlayer insulating layer I2 to be electrically connected to the test circuit lower contact pad 45. The test circuit upper contact pad 75 may be disposed on the test circuit upper contact plug 65 and the middle-upper interlayer insulating layer I3 to vertically overlap and be electrically connected to the test circuit upper contact plug 65. The test circuit lower contact pad 55 and/or the test circuit upper contact pad 75 may each have a segment shape elongated in the horizontal direction. Elements of the test circuit structure TCS may include at least one of a capacitor structure, a resistance structure, a transistor structure, or a bridge structure. The test circuit lower contact plug 45, the test circuit lower contact pad 55, the test circuit upper contact plug 65, and the test circuit upper contact pad 75 may each include a conductor such as a metal, a metal alloy, or a metal nitride.

The test pad structure TPS may include a test pad lower contact plug 46, a test pad lower contact pad 56, a test pad middle contact plug 66, a test pad middle contact pad 76, a test pad upper contact plug 86, and a test pad upper contact pad 96. The test pad lower contact plug 46 may vertically pass through the lower interlayer insulating layer I1 to be physically and electrically connected to the test pad connection part 25. The test pad lower contact pad 56 may be disposed on the test pad lower contact plug 46 and the lower interlayer insulating layer I1 to vertically overlap and be electrically connected to the test pad lower contact plug 46. The test pad middle contact plug 66 may vertically pass through the middle-upper interlayer insulating layer I3 and the middle-lower interlayer insulating layer I2 to vertically overlap and be electrically connected to the test pad lower contact pad 56. The test pad middle contact pad 76 may be disposed on the test pad middle contact plug 66 and the middle-upper interlayer insulating layer I3. The test pad middle contact pad 76 may vertically overlap and be electrically connected to the test pad middle contact plug 66. The test pad upper contact plug 86 may vertically pass through the upper interlayer insulating layer I4 to vertically overlap and be electrically connected to the test pad middle contact pad 76. The test pad upper contact pad 96 may be disposed on the test pad upper contact plug 86 and the upper interlayer insulating layer I4. The test pad upper contact pad 96 may vertically overlap and be electrically connected to the test pad upper contact plug 86. The test pad upper contact pad 96 may correspond to the first test pad TP1 of FIGS. 2A, 2C, and 3A. The test pad lower contact pad 56, the test pad middle contact pad 76, and the test pad upper contact pad 96 may have a segment shape elongated in the first horizontal direction X or the second horizontal direction Y. The test pad lower contact plug 46, the test pad middle contact plug 66, and the test pad upper contact plug 86 may have a pillar shape extending in the vertical direction Z. The test pad lower contact plug 46, the test pad lower contact pad 56, the test pad middle contact plug 66, the test pad middle contact pad 76, the test pad upper contact plug 86, and the test pad upper contact pad 96 may each include a conductor such as a metal, a metal alloy, or a metal nitride.

The test pad connection part 25 may be buried in the guard ring isolation (shallow trench isolation, STI) region 10 formed in the substrate Sub. The test pad connection part 25 may include a test pad connection buried electrode 25a and a test pad connection buried capping layer 25b. The test pad connection buried electrode 25a may include a conductor such as a metal, a metal alloy, or a metal nitride. The test pad connection buried capping layer 25b may include a silicon nitride layer. The test circuit lower contact plug 45 and the test pad connection buried electrode 25a of the test pad connection part 25 may include the same material. Therefore, the test circuit lower contact plug 45 and the test pad connection part 25 can be bonded very strongly compared to different materials from each other. The lower interlayer insulating layer I1 may be disposed on the substrate Sub to surround side surfaces of the guard ring lower electrode 30, the guard ring lower plug 40, the test circuit lower contact plug 45, and the test pad lower contact plug 46. The middle-lower interlayer insulating layer I2 may be disposed on the lower interlayer insulating layer I1 to surround side surfaces of the guard ring lower pad 50, the guard ring middle plug 60, the test circuit lower contact pad 55, the test circuit middle contact plug 65, the test pad lower contact pad 56, and the test pad middle contact plug 66.

The upper interlayer insulating layer I3 may be disposed on the middle-lower interlayer insulating layer I2 to surround side surfaces of the guard ring middle plug 60, the test circuit upper contact plug 65, and the test pad middle contact plug 66. The uppermost interlayer insulating layer I4 may be disposed on the upper interlayer insulating layer I3 to surround side surfaces of the guard ring middle pad 70, the guard ring upper plug 80, the test circuit upper contact pad 75, the test pad middle contact pad 76, and the test pad upper contact plug 86.

The guard ring upper pads 90 of the guard ring structure GSa may correspond to the uppermost metal layer of the semiconductor device, and may contact the probe pin for testing. The guard ring structure GSa may have a loss-less connection structure from the surface of the substrate Sub to the uppermost metal layer. Therefore, the guard ring structure GSa may prevent moisture penetration and crack propagation from the scribe lane SL to the chip area CA.

Referring to FIG. 5, the semiconductor device may include a guard ring structure GSb, a crack detection pad structure CPS, and a crack detection pad connection part 23. The guard ring structure GSb may include an inner guard ring structure GSi, an outer guard ring structure GSo, and a crack detection circuit structure CDS. The semiconductor device may further include a lower interlayer insulating layer I1, a middle-lower interlayer insulating layer I2, a middle-upper interlayer insulating layer I3, and an upper interlayer insulating layer I4.

The inner guard ring structure GSi may include an inner guard ring lower electrode 31, an inner guard ring lower plug 41, an inner guard ring lower pad 51, an inner guard ring middle plug 61, an inner guard ring middle pad 71, an inner guard ring upper plug 81, and an inner guard ring upper pad 91. The inner guard ring lower electrode 31 may be formed directly on the surface of the substrate Sub. The inner guard ring lower electrode 31 may include an insulating lower layer, a conductive middle layer, and an insulating upper layer. The inner guard ring lower plug 41 may vertically pass through the lower interlayer insulating layer I1 and may be disposed on the inner guard ring lower electrode 31. The inner guard ring lower plug 41 may vertically pass through the insulating upper layer of the inner guard ring lower electrode 31 to be electrically connected to the conductive middle layer of the inner guard ring lower electrode 31. The inner guard ring lower pad 51 may be disposed on the inner guard ring lower plug 41 and the lower interlayer insulating layer I1. The inner guard ring lower pad 51 may vertically overlap and be electrically connected to the inner guard ring lower plug 41. The inner guard ring middle plug 61 may vertically pass through the middle-upper interlayer insulating layer I3 and the middle-lower interlayer insulating layer I2 to vertically overlap and be electrically connected to the inner guard ring lower pad 51. The inner guard ring middle pad 71 may be disposed on the inner guard ring middle plug 61 and the middle-upper interlayer insulating layer I3. The inner guard ring middle pad 71 may vertically overlap and be electrically connected to the inner guard ring middle plug 61. The inner guard ring upper plug 81 may vertically pass through the upper interlayer insulating layer I4 to vertically overlap and be electrically connected to the inner guard ring middle pad 71. The inner guard ring upper pad 91 may be disposed on the inner guard ring upper plug 81 and the upper interlayer insulating layer I4. The inner guard ring upper pad 91 may vertically overlap and be electrically connected to the inner guard ring upper plug 81. The inner guard ring lower electrode 31, the inner guard ring lower pad 51, the inner guard ring middle pad 71, and the inner guard ring upper pad 91 may each have a segment shape elongated in the first horizontal direction X and a line shape extending in the second horizontal direction Y. The inner guard ring lower plug 41, the inner guard ring middle plug 61, and the inner guard ring upper plug 81 may each have a wall shape extending in the vertical direction Z. The inner guard ring lower electrode 31, the inner guard ring lower plug 41, the inner guard ring lower pad 51, the inner guard ring middle plug 61, the inner guard ring middle pad 71, the inner guard ring upper plug 81, and the inner guard ring upper pad 91 may each include a conductor such as a metal, a metal alloy, or a metal nitride.

The outer guard ring structure GSo may include an outer guard ring lower plug 42, an outer guard ring lower pad 52, an outer guard ring middle plug 62, an outer guard ring middle pad 72, an outer guard ring upper plug 82, and an outer guard ring upper pad 92. The outer guard ring lower plug 42 may vertically pass through the lower interlayer insulating layer I1. The guard ring isolation region 10 in the substrate Sub may define the guard ring active region 3. The outer guard ring lower pad 52 may be disposed on the outer guard ring lower plug 42 and the lower interlayer insulating layer I1. The outer guard ring lower pad 52 may vertically overlap and be electrically connected to the outer guard ring lower plug 42. The outer guard ring middle plug 62 may vertically pass through the middle-upper interlayer insulating layer I3 and the middle-lower interlayer insulating layer I2 to vertically overlap and be electrically connected to the outer guard ring lower pad 52. The outer guard ring middle pad 72 may be disposed on the outer guard ring middle plug 62 and the middle-upper interlayer insulating layer I3. The outer guard ring middle pad 72 may vertically overlap and be electrically connected to the outer guard ring middle plug 62. The outer guard ring upper plug 82 may vertically pass through the upper interlayer insulating layer I4 to vertically overlap and be electrically connected to the outer guard ring middle pad 72. The outer guard ring upper pad 92 may be disposed on the outer guard ring upper plug 82 and the upper interlayer insulating layer I4. The outer guard ring upper pad 92 may vertically overlap and be electrically connected to the outer guard ring upper plug 82. The outer guard ring lower pad 52, the outer guard ring middle pad 72, and the outer guard ring upper pad 92 may each have a segment shape elongated in the first horizontal direction X and a line shape extending in the second horizontal direction Y. The outer guard ring lower plug 42, the outer guard ring middle plug 62, and the outer guard ring upper plug 82 may each have a wall shape extending in the vertical direction Z. The outer guard ring lower plug 42, the outer guard ring lower pad 52, the outer guard ring middle plug 62, the outer guard ring middle pad 72, the outer guard ring upper plug 82, and the outer guard ring upper pad 92 may each include a conductor such as a metal, a metal alloy, or a metal nitride.

The crack detection circuit structure CDS may include a crack detection circuit lower contact plug 43, a crack detection circuit lower contact pad 53, a crack detection circuit middle contact plug 63, a crack detection circuit middle contact pad 73, a crack detection circuit upper contact plug 83, and a crack detection circuit upper contact pad 93. The crack detection circuit lower contact plug 43 may vertically pass through the lower interlayer insulating layer I1 to be physically and electrically connected to the crack detection pad connection part 23. The crack detection circuit lower contact pad 53 may be disposed on the crack detection circuit lower contact plug 43 and the lower interlayer insulating layer I1. The crack detection circuit lower contact pad 53 may vertically overlap and be electrically connected to the crack detection circuit lower contact plug 43. The crack detection circuit middle contact plug 63 may vertically pass through the middle-upper interlayer insulating layer I3 and the middle-lower interlayer insulating layer I2 to vertically overlap and be electrically connected to the crack detection circuit lower contact pad 53. The crack detection circuit middle contact pad 73 may be disposed on the crack detection circuit middle contact plug 63 and the middle-upper interlayer insulating layer I3. The crack detection circuit middle contact pad 73 may vertically overlap and be electrically connected to the crack detection circuit middle contact plug 63. The crack detection circuit upper contact plug 83 may vertically pass through the upper interlayer insulating layer I4 to vertically overlap and be electrically connected to the crack detection circuit middle contact pad 73. The crack detection circuit upper contact pad 93 may be disposed on the crack detection circuit upper contact plug 83 and the upper interlayer insulating layer I4. The crack detection circuit upper contact pad 93 may vertically overlap and be electrically connected to the crack detection circuit upper contact plug 83. The crack detection circuit lower contact pad 53, the crack detection circuit middle contact pad 73, and the crack detection circuit upper contact pad 93 may each have a segment shape elongated in the first horizontal direction X or the second horizontal direction Y. The crack detection circuit lower contact plug 43, the crack detection circuit middle contact plug 63, and the crack detection circuit upper contact plug 83 may each have a pillar shape extending in the vertical direction Z. The crack detection circuit lower contact plug 43, the crack detection circuit lower contact pad 53, the crack detection circuit middle contact plug 63, the crack detection circuit middle contact pad 73, the crack detection circuit upper contact plug 83, and the crack detection circuit upper contact pad 93 may each include a conductor such as a metal, a metal alloy, or a metal nitride.

The crack detection pad structure CPS may include a crack detection pad lower contact plug 44, a crack detection pad lower contact pad 54, a crack detection pad middle contact plug 64, a crack detection pad middle contact pad 74, a crack detection pad upper contact plug 84, and a crack detection pad upper contact pad 94. The crack detection pad lower contact plug 44 may vertically pass through the lower interlayer insulating layer I1 to be physically and electrically connected to the crack detection pad connection part 23. The crack detection pad lower contact pad 54 may be disposed on the crack detection pad lower contact plug 44 and the lower interlayer insulating layer I1 to vertically overlap and be electrically connected to the crack detection pad lower contact plug 44. The crack detection pad middle contact plug 64 may vertically pass through the middle-upper interlayer insulating layer I3 and the middle-lower interlayer insulating layer I2 to vertically overlap and be electrically connected to the crack detection pad lower contact pad 54. The crack detection pad middle contact pad 74 may be disposed on the crack detection pad middle contact plug 64 and the middle-upper interlayer insulating layer I3. The crack detection pad middle contact pad 74 may vertically overlap and be electrically connected to the crack detection pad middle contact plug 64. The crack detection pad upper contact plug 84 may vertically pass through the upper interlayer insulating layer I4 to vertically overlap and be electrically connected to the crack detection pad middle contact pad 74. The crack detection pad upper contact pad 94 may be disposed on the crack detection pad upper contact plug 84 and the upper interlayer insulating layer I4. The crack detection pad upper contact pad 94 may vertically overlap and be electrically connected to the crack detection pad upper contact plug 84. The crack detection pad lower contact pad 54, the crack detection pad middle contact pad 74, and the crack detection pad upper contact pad 94 may each have a segment shape elongated in the first horizontal direction X or the second horizontal direction Y. The crack detection pad lower contact plug 44, the crack detection pad middle contact plug 64, and the crack detection pad upper contact plug 84 may each have a pillar shape extending in the vertical direction Z. The crack detection pad lower contact plug 44, the crack detection pad lower contact pad 54, the crack detection pad middle contact plug 64, the crack detection pad middle contact pad 74, the crack detection pad upper contact plug 84, and the crack detection pad upper contact pad 94 may each include a conductor such as a metal, a metal alloy, or a metal nitride.

The crack detection connection part 23 may be buried in the guard ring isolation region 10 formed in the substrate Sub. The crack detection pad connection part 23 may include a crack detection connection buried electrode 23a and a crack detection connection buried capping layer 23b. The crack detection pad connection buried electrode 23a may include a conductor such as a metal, a metal alloy, or a metal nitride. The crack detection pad connection buried capping layer 25b may include a silicon nitride based insulating layer. The crack detection circuit lower contact plug 43, the crack detection pad lower contact plug 44, and the crack detection pad connection buried electrode 23a of the crack detection pad connection part 23 may include the same material. Therefore, adhesion and bonding of the crack detection circuit lower contact plug 43 and the crack detection pad connection buried electrode 23a, and adhesion and bonding of the crack detection pad lower contact plug 44 and the crack detection pad connection buried electrode 23a can be bonded very strongly compared to different materials from each other.

The inner and outer guard ring upper pads 91 and 92 of the guard ring structure GSb may correspond to the uppermost metal layer of the semiconductor device and may be in contact with a probe pin for crack detection. The inner and outer guard ring structures GSi and GSo of the guard ring structure GSb may have a loss-less connection structure from the surface of the substrate Sub to the uppermost metal layer. Therefore, the guard ring structure GSb may prevent moisture penetration and crack propagation from the scribe lane SL to the chip area CA.

Referring to FIG. 6, a semiconductor device according to an embodiment of the present disclosure may include a cell structure CS. The cell structure CS may include a cell isolation region 18 and buried gate lines 28 in a substrate Sub, and a bit line contact plug 37, a bit line 38, a storage contact plug 48, a storage contact pad 58, and a storage electrode 68 on the substrate Sub, in a vertical direction Z. The semiconductor device may further include a lower interlayer insulating layer I1, a middle-lower interlayer insulating layer I2, a middle-upper interlayer insulating layer I3, and an upper interlayer insulating layer I4. The cell isolation region 18 may define a cell active region 8. The cell isolation region 18 may include an insulating material. The buried gate lines 28 may include buried gate electrodes 28a and buried gate capping layers 28b formed in buried gate trenches Tb. The buried gate electrodes 28a may include a conductor such as a metal, a metal alloy, or a metal nitride. The buried gate electrodes 28a may be formed to be larger and deeper in the cell isolation region 18 than in the cell active region 8. The buried gate lines 28 may be formed in the same structure and at the same level as the crack detection pad connection parts 23a and 24a and the test pad connection parts 25a and 26a, and may include the same material.

The bit line contact plug 37 may have a pillar shape electrically connected to a central portion of the cell active region 8. The bit line contact plug 37 may include at least one of doped silicon, metal silicide, metal nitride, metal, or metal alloy. The bit line 38 may be electrically connected to the bit line contact plug 37 to extend in a horizontal direction. The bit line 38 may include an insulating lower layer, a conductive middle layer, and an insulating upper layer. The conductive middle layer of the bit line 38 may be directly connected to the upper surface of the bit line contact plug 37. The bit line contact plug 37 may pass through the insulating lower layer to be electrically connected to the conductive middle layer.

The storage contact plugs 48 may each have a pillar shape vertically passing throughs the lower interlayer insulating layer I1 and be electrically connected to portions of both sides of the cell active region 8. The storage contact plugs 48 may include at least one of doped silicon, metal silicide, metal nitride, metal, or metal alloy. The storage contact pads 58 may be disposed between the storage contact plugs 48 and the storage electrodes 68 on the lower interlayer insulating layer I1 to be electrically connected to the storage contact plugs 48 to the storage electrodes 68. The storage contact pads 58 may include at least one of doped silicon, metal silicide, metal nitride, metal, or metal alloy. The storage electrodes 68 may vertically pass through the middle-lower interlayer insulating layer I2 and may be disposed on the storage contact pads 58. The storage electrodes 68 may include at least one of doped silicon, metal silicide, metal nitride, metal, or metal alloy.

The lower interlayer insulating layer I1 may surround side surfaces of the bit line contact plug 37, the bit line 38, and the storage contact plugs 48. The lower interlayer insulating layer I1 may surround a portion and an upper surface of a lower surface of the bit line 38. The middle-lower interlayer insulating layer I2 may surround side surfaces of the storage contact pads 58 and the storage electrodes 68. The middle-lower interlayer insulating layer I2 may cover portions of upper surfaces of the storage contact pads 58. The middle-upper interlayer insulating layer I3 may be disposed on upper surfaces of the storage electrodes 68. That is, the middle-upper interlayer insulating layer I3 may not surround the side surfaces of the storage electrodes 68.

Referring to FIG. 7, a semiconductor device according to an embodiment of the present disclosure may include a peripheral transistor structure TS. The peripheral transistor structure TS, in the vertical direction Z, may include a peripheral isolation region 19 in a substrate Sub, a peripheral gate electrode 39, a peripheral lower contact plug 49, a peripheral lower contact pad 59, a peripheral upper contact pad 79, a peripheral upper contact plug 89, and a peripheral interconnection line 99 on the substrate Sub. The peripheral isolation region 19 may define the peripheral active region 9. The peripheral isolation region 19 may include an insulating material. The peripheral gate electrode 39 may include a conductor. The peripheral gate electrode 39 may have the same structure as the bit line 38 of the cell structure CS. For example, the peripheral gate electrode 39 may include an insulating lower layer, a conductive middle layer, and an insulating upper layer, respectively corresponding to features of the bit line 38 of the cell structure CS. The peripheral lower contact plug 49 may vertically pass through the lower interlayer insulating layer I1 to be physically and electrically connected to the peripheral active region 9 of the substrate Sub. The peripheral lower contact pad 59 may be disposed on the peripheral lower contact plug 49 and the lower interlayer insulating layer I1. The peripheral lower contact pad 59 may vertically overlap and be electrically connected to the peripheral lower contact plug 49. The peripheral middle contact plug 69 may vertically pass through the middle-upper interlayer insulating layer I3 and the lower interlayer insulating layer I2 to vertically overlap and be electrically connected to the peripheral lower contact pad 59. The peripheral middle contact pad 79 may be disposed on the peripheral middle contact plug 69 and the middle-upper interlayer insulating layer I3. The peripheral middle contact pad 79 may vertically overlap and be electrically connected to the peripheral middle contact plug 69. The peripheral upper contact plug 89 may vertically pass through the upper interlayer insulating layer I4 to vertically overlap and be electrically connected to the peripheral middle contact pad 79. The peripheral upper contact pad 99 may be disposed on the peripheral upper contact plug 89 and the upper interlayer insulating layer I4. The peripheral upper contact pad 99 may vertically overlap and be electrically connected to the peripheral upper contact plug 89.

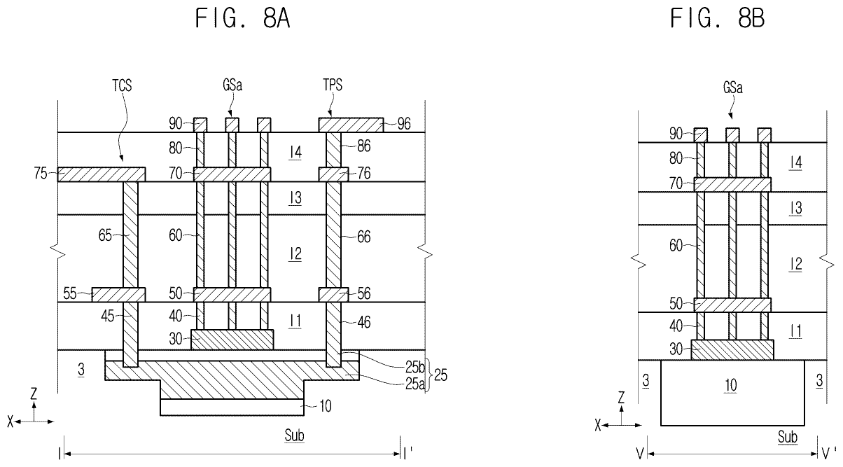

FIG. 8A is a longitudinal sectional view taken along the line I-I′ of FIG. 3A, and FIG. 8B is a longitudinal sectional view taken along the line V-V′ of FIG. 3A. Referring to FIGS. 8A and 8B, the semiconductor device may include a guard ring structure GSa, a test circuit structure TCS, a test pad structure TPS, and a test pad connection part 25. The guard ring structure GSa may be disposed on a guard ring isolation region 10 formed in a substrate Sub. The guard ring lower electrode 30 may be electrically insulated from the guard ring active region 3 by the guard ring isolation region 10. The guard ring lower electrode 30 may be electrically insulated from the test pad connection buried electrode 25a by the test pad connection buried capping layer 25b. The guard ring lower electrode 30 may be electrically insulated from the guard ring lower electrode 3 by the guard ring isolation region 10. The test pad connection part 25 may cross the guard ring isolation region 10 in the first horizontal direction X. A portion of the test pad connection buried electrode 25a in the guard ring isolation region 10 may be formed deeper and larger than a portion of the test pad connection buried electrode 25a in the guard ring active region 3.

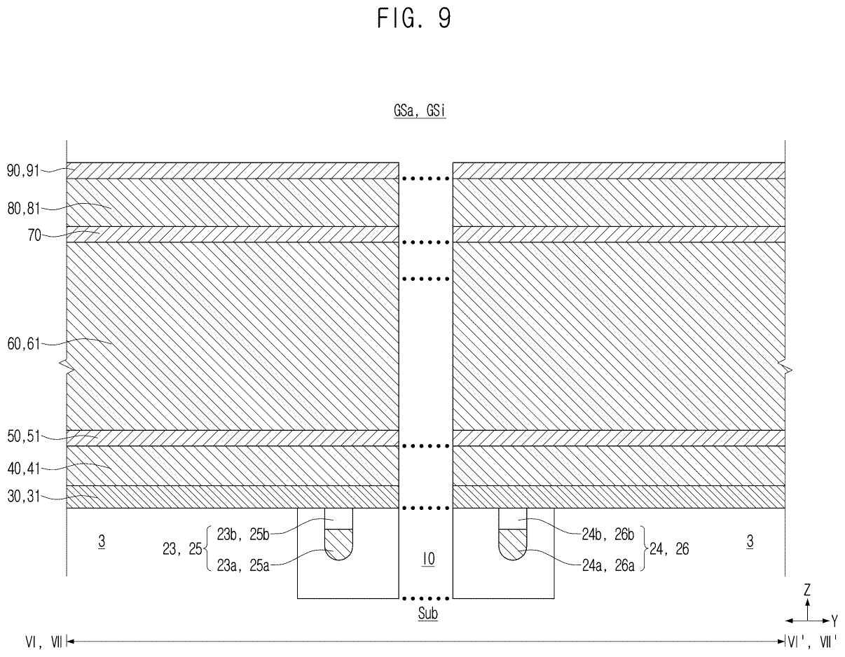

FIG. 9 is a longitudinal sectional view taken along the lines VI-VI′ of FIG. 3A or VII-VII′ of FIG. 3B. Referring to FIG. 9, guard ring structures GSa and GSi may include guard ring lower electrodes 30 and 31, guard ring lower plugs 40, 41, guard ring lower plugs 50, 51, guard ring middle plugs 60, 61, guard ring middle plugs 70, 71, guard ring upper plugs 80, 81, and guard ring upper pads 90 and 91. The crack detection pad connection parts 23 and 24 and/or test pad connection parts 25 and 26 may cross lower portions of guard ring structures GSa and GSi.

Each of the guard ring lower electrodes 30 and 31 and the upper contact pads 90 and 91 may have a line shape extending in the second horizontal direction Y. Each of the guard ring lower electrodes 30 and 31, the guard ring lower pads 50 and 51, the guard ring middle pads 70, and the guard ring upper pads 90 and 91 may have a wall shape extending in the second direction Y and the vertical direction Z.

The crack detection pad connection parts 23 and 24 and/or the test pad connection parts 25 and 26 may be buried in the guard ring isolation region 10 in the substrate Sub. The guard ring lower electrodes 30 and 31 may be electrically insulated from the crack-detection pad connection buried electrodes 23a and 24a and/or the test pad connection buried electrodes 25a and 26a by the crack-detection pad connection buried capping layers 23b and 24b, and/or the test pad connection buried capping layers 25b and 26b.

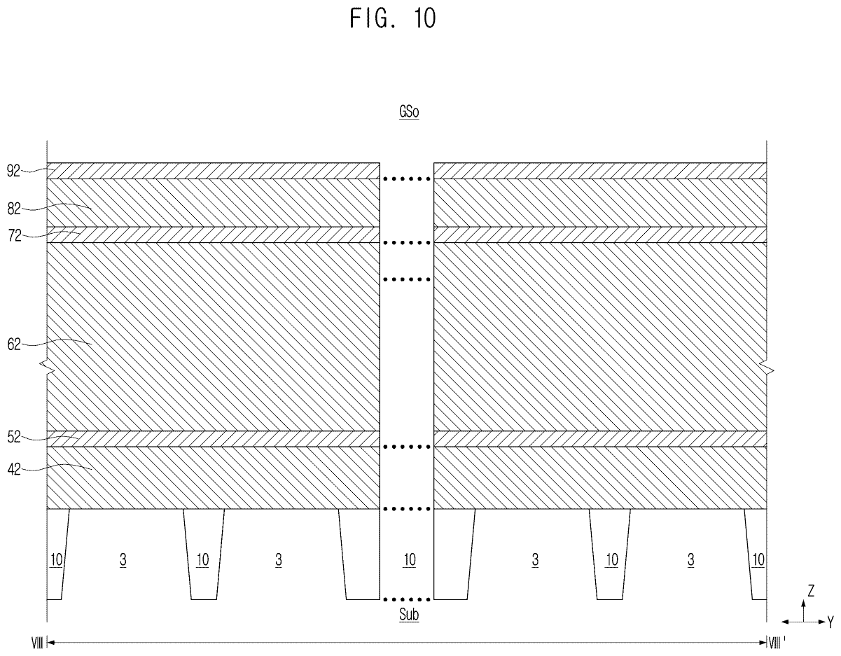

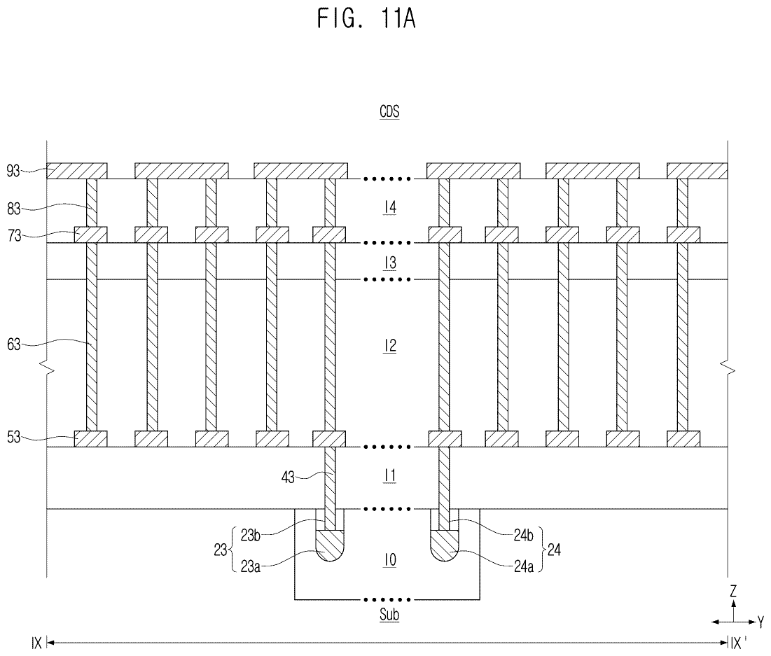

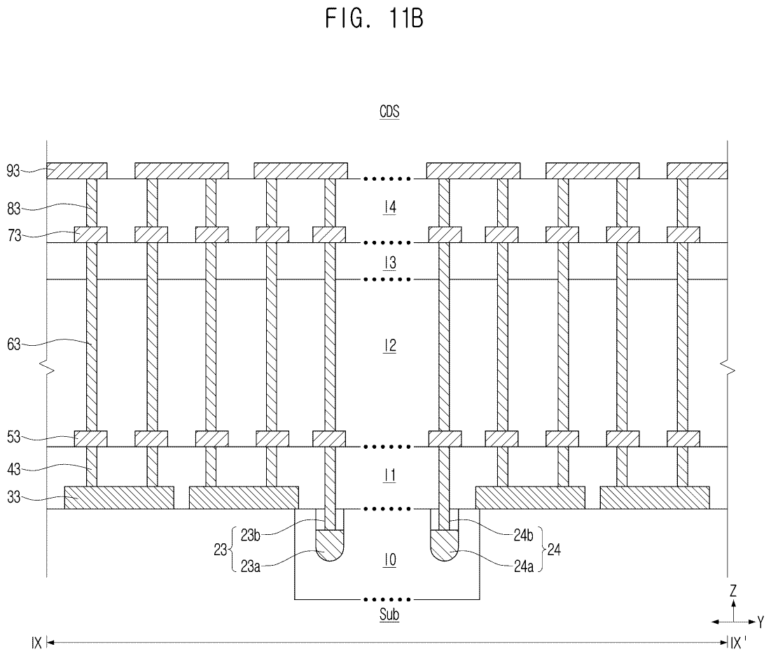

FIG. 10 is a longitudinal sectional view taken along the line VIII-VIII′ of FIG. 3B. Referring to FIG. 10, the outer guard ring structure GSo may include outer guard ring lower plugs 42, outer guard ring lower pads 52, outer guard ring middle plugs 62, outer guard ring middle pads 72, outer guard ring upper plugs 82, and outer guard ring upper pads 92. The guard ring isolation regions 10 may define the guard ring active regions 3. The guard ring lower plugs 42 may abut the guard ring active regions 3 and the guard ring isolation regions 10.

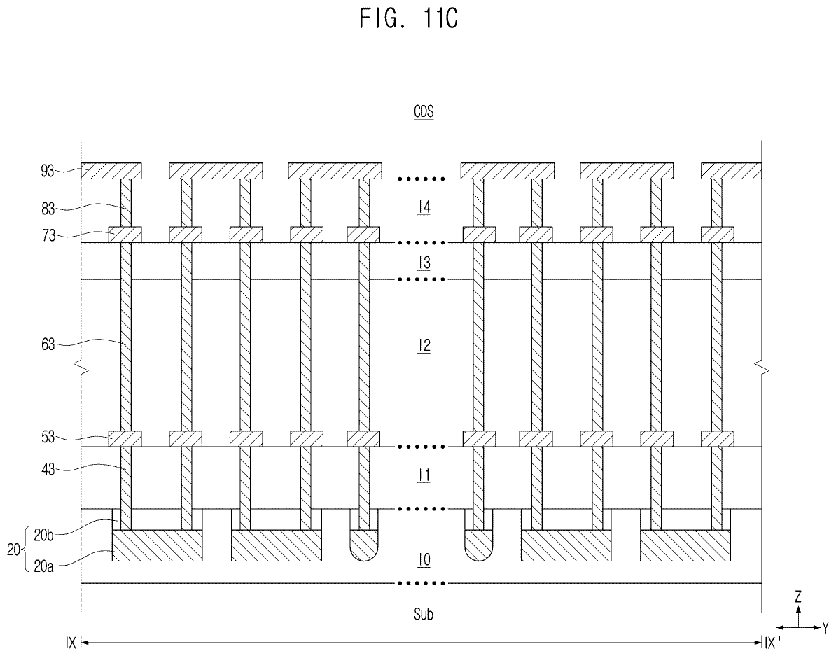

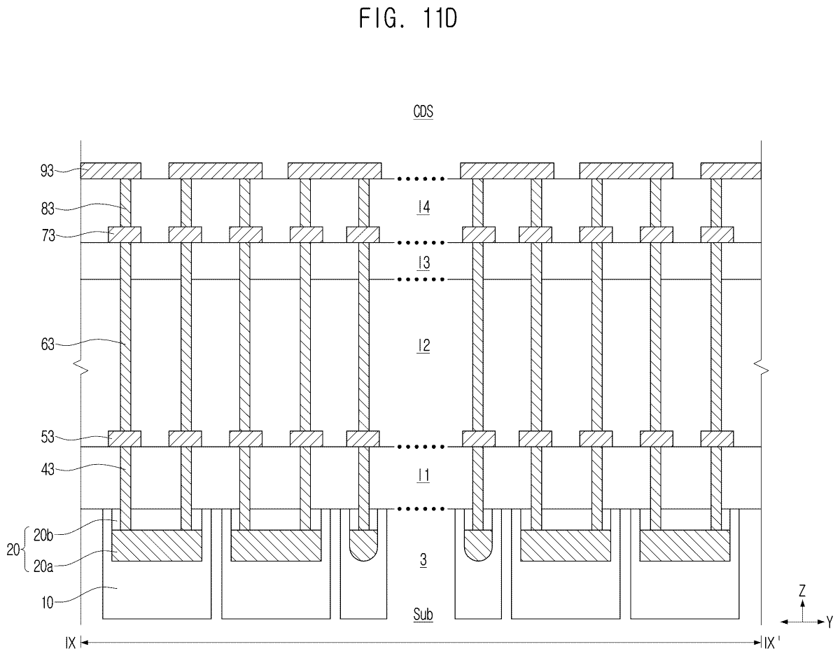

FIGS. 11A to 11D are longitudinal cross-sectional views taken along the line IX-IX′ of FIG. 3B. Referring to FIGS. 11A to 11D, each of the semiconductor devices may include a crack detection circuit structure CDS and crack detection pad connection parts 23 and 24.

Referring to FIG. 11A, the crack detection circuit structure CDS may include crack detection circuit lower contact plugs 43, crack detection circuit lower contact pads 53, crack detection circuit middle contact plugs 63, crack detection circuit middle contact pads 73, crack detection circuit upper contact plugs 83, and crack detection circuit upper contact pads 93. The crack detection pad connection parts 23 and 24 may be buried in a guard ring isolation region 10 in a substrate Sub.

The crack detection circuit lower contact pad 53 may be spaced apart from the substrate Sub in the vertical direction Z and may be disposed on a lower interlayer insulating layer I1. The crack detection circuit lower contact pads 53 may each have a segment shape elongated in the second horizontal direction Y. The crack detection circuit lower contact pads 53 may electrically connect crack detection middle contact plugs 63 adjacent with each other in the second horizontal direction Y.

The crack detection circuit lower contact pads 53 and the crack detection circuit upper contact pads 93 may be offset arranged. In the second horizontal direction Y, the crack detection circuit lower contact pads 53 may electrically connect odd-numbered crack detection circuit lower contact plugs 43 and even-numbered crack detection circuit lower contact plugs 43 to each other. In the second horizontal direction Y, the crack detection circuit upper contact pads 93 may electrically connect the even-numbered crack detection circuit upper contact plugs 83 and the odd-numbered crack detection circuit upper contact plugs 83 to each other.

Some of the crack detection circuit lower contact pads 53 may not extend or elongate in the second horizontal direction Y. Each of the crack detection circuit lower contact plug 43 may vertically and electrically connect one of the crack detection circuit lower contact pads 53 that does not extend to one of the crack detection pad connection parts 23 and 24. The crack detection pad connection parts 23 and 24 may include a first crack detection pad connection part 23 and a second crack detection pad connection part 24. The first and second crack detection pad connection parts 23 and 24 may include first and second crack detection pad connection buried electrodes 23a and 24a, and first and second crack detection pad connection buried capping layers 23b and 24b, respectively. Thus, the crack detection circuit lower contact plugs 43 may be electrically connected to the first and second crack detection pad connection buried electrodes 23a and 24a, respectively.

Referring to FIG. 11B, the crack detection circuit structure CDS may include crack detection circuit lower electrodes 33, crack detection circuit lower contact plugs 43, crack detection circuit lower contact pads 53, crack detection circuit middle contact plugs 63, crack detection circuit middle contact pads 73, crack detection circuit upper contact plugs 83, and crack detection circuit upper contact pads 93. The crack detection pad connection parts 23 and 24 may be buried in the guard ring isolation region 10 in the substrate Sub. The crack detection circuit lower electrodes 33 may be disposed on the substrate Sub to each have a segment shape elongated in the second horizontal direction Y. The crack detection pad connection parts 23 and 24 may be buried in the guard ring isolation region 10 in the substrate Sub.

Some of the crack detection circuit lower contact plugs 43 may electrically connect the crack detection lower contact pads 53 and the crack detection circuit lower electrodes 33. The other portions of the crack detection circuit lower contact plugs 43 may electrically connect the crack detection lower contact pads 53 to the crack detection pad connection parts 23 and 24.

The crack detection circuit lower electrodes 33 and the crack detection circuit upper contact pads 93 may be offset arranged. In the second horizontal direction Y, the crack detection circuit lower electrodes 33 may electrically connect the odd-numbered crack detection circuit lower contact plugs 43 and the even-numbered crack detection circuit lower contact plugs 43 to each other. In the second horizontal direction Y, the crack detection circuit upper contact pads 93 may electrically connect the even-numbered crack detection circuit upper contact plugs 83 and the odd-numbered crack detection circuit upper contact plugs 83 to each other.

The crack detection pad connection parts 23 and 24 may include a first crack detection pad connection part 23 and a second crack detection pad connection part 24. The first and second crack detection pad connection parts 23 and 24 may include first and second crack detection pad connection buried electrodes 23a and 24a, and first and second crack detection pad connection buried capping layers 23b and 24b, respectively. Therefore, the other portions of the crack detection circuit lower contact plugs 33 may be electrically connected to the first and second crack detection pad connection buried electrodes 23a and 24a, respectively.

Referring to FIGS. 11C and 11D, a crack detection circuit structure CDS may include crack detection circuit buried interconnections 20, crack detection circuit lower contact plugs 43, crack detection circuit lower contact pads 53, crack detection circuit middle contact plugs 63, crack detection circuit upper contact plugs 83, and crack detection circuit upper contact pads 93. The crack detection circuit buried interconnections 20 may be buried in the guard ring isolation region 10 in the substrate Sub. The crack detection circuit buried interconnections 20 may include crack detection circuit buried electrodes 20a and crack detection circuit buried capping layers 20b. The crack detection circuit buried interconnections 20 may have the same structure as the crack detection pad connection parts 23 and 24. The crack detection circuit lower contact plugs 43 may be directly and electrically connected to the crack detection circuit buried electrodes 20a of the crack detection circuit buried interconnections 20. The crack detection circuit buried interconnections 20 and the crack detection circuit upper contact pads 93 may be offset arranged. Referring to FIG. 11C, the guard ring isolation region 10 may be formed as a whole to surround the crack detection circuit buried interconnections 20. Referring to FIG. 11D, the guard ring isolation region 10 may be formed as a plurality to surround one of the crack detection circuit buried interconnections 20.

The crack detection circuit buried interconnections 20, the crack detection pad connection parts 23 and 24, the test pad connection parts 25 and 26, and the buried gate electrodes 28a may be formed simultaneously and may be formed to have the same structure at the same level. The crack detection circuit buried electrodes 20a, the crack detection pad connection buried electrodes 23a and 24a, the test pad connection buried electrodes 25a and 26a, the buried gate electrodes 28a, the guard ring lower plugs 40, the inner guard ring lower plugs 41, the outer guard ring lower plugs 42, the crack detection circuit lower contact plugs 43, the crack detection pad lower contact plugs 44, the test circuit lower contact plugs 45, and the test pad lower contact plugs 46 may include the same metal. Therefore, adhesion force and bonding force may be improved because of the same material.

The guard ring lower electrodes 30, the inner guard ring lower electrodes 31, the crack detection circuit lower electrodes 33, and the peripheral gate electrode 39 may have the same structure. For example, the guard ring lower electrodes 30, the inner guard ring lower electrodes 31, the crack detection circuit lower electrodes 33, and the peripheral gate electrodes 39 may have a gate structure with an insulating lower layer, a conductive middle layer, and an insulating upper layer. The insulating lower layer may include at least one of a silicon oxide based insulating layer, a metal oxide based insulating layer, or a silicon nitride based insulating layer. The conductive middle layer may include at least one of a metal such as tungsten, a metal nitride such as titanium nitride, and a metal silicide such as cobalt silicide. The insulating upper layer may include an insulating layer based silicon nitride layer.

The guard ring lower electrodes 30, the inner guard ring lower electrodes 31, the crack detection circuit lower electrodes 33, and the peripheral gate electrode 39 may be formed simultaneously in the same process.

According to the embodiments of the present disclosure, the guard ring structure can maintain structural stability and physical robustness.

According to the embodiments of the present disclosure, the pad structures of the test circuit and the crack detection circuit can be disposed in the chip area.

According to the embodiments of the present disclosure, test circuits and crack detection circuits can be connected to pad structures without structural and physical loss of the guard ring structure.

While the present invention has been described with respect to specific embodiments, it will be apparent to those skilled in the art that various changes and modifications may be made without departing from the technical concepts and scope of the disclosure as defined in the following claims. Furthermore, the embodiments may be combined to form additional embodiments.

What is claimed is:

1. A semiconductor device comprising:
a substrate having a chip area and a guard ring area which is disposed to surround the chip area;
a guard ring structure and a crack detection circuit structure which are disposed over the substrate in the guard ring area;
a crack detection pad structure disposed over the substrate in the chip area; and
a crack detection pad connection part buried in the substrate to electrically connect the crack detection circuit structure to the crack detection pad structure across a portion of the guard ring structure,
wherein the crack detection pad connection part includes a crack detection pad connection buried electrode and a crack detection pad connection buried capping layer which is disposed over the crack detection pad connection buried electrode.

2. The semiconductor device of claim 1, further comprising a cell structure disposed in the chip area,
wherein the cell structure includes:
a cell isolation region disposed in the substrate to define a cell active region; and
a buried gate line buried in the substrate, the buried gate line including a buried gate electrode and a buried gate capping layer which is disposed over the buried gate electrode,
wherein the crack detection pad connection buried electrode and the buried gate electrode are disposed at a same level, and
wherein the crack detection pad connection buried capping layer and the buried gate capping layer are disposed at a same level.

3. The semiconductor device of claim 1,
wherein the guard ring structure includes an inner guard ring structure and an outer guard ring structure,
wherein the crack detection circuit structure is disposed between the inner guard ring structure and the outer guard ring structure, and
wherein the crack detection pad connection part is disposed across the inner guard ring structure.

4. The semiconductor device of claim 3,
wherein the inner guard ring structure includes:
inner guard ring lower electrodes disposed over the substrate;
inner guard ring lower plugs disposed over the inner guard ring lower electrodes;
inner guard ring upper plugs disposed over the inner guard ring lower plugs; and
inner guard ring upper pads disposed over the inner guard ring upper plugs,
wherein each of the inner guard ring lower electrodes and each of the inner guard ring upper pads have a line shape extending in a horizontal direction, and
wherein each of the inner guard ring lower plugs and each of the inner guard ring upper plugs have a wall shape extending in a vertical direction.

5. The semiconductor device of claim 4, further comprising a peripheral transistor structure disposed in the chip area,
wherein the peripheral transistor structure includes:
a peripheral isolation region disposed in the substrate to define a peripheral active region; and
a peripheral gate electrode disposed over the peripheral active region, and
wherein the peripheral gate electrode and the inner guard ring lower plugs are disposed at a same level.

6. The semiconductor device of claim 3,
wherein the outer guard ring structure includes:
outer guard ring lower plugs electrically connected to the substrate;
outer guard ring upper plugs disposed over the guard ring outer lower contact plugs; and
outer guard ring upper pads disposed over the outer guard ring upper plugs,
wherein each of the outer guard ring lower plugs and each of the outer guard ring upper plugs has a wall shape extending in a vertical direction, and
wherein each of the outer guard ring upper pads has a line shape extending in a horizontal direction.

7. The semiconductor device of claim 6, further comprising a guard ring isolation region disposed in the substrate to define a guard ring active region,
wherein the outer guard ring lower plugs are electrically connected to the guard ring active region, and
wherein the crack detection pad connection part is buried in the guard ring isolation region.

8. The semiconductor device of claim 7,
wherein the crack detection circuit structure includes:
a crack detection circuit lower contact plug;
crack detection circuit lower contact pads disposed to be spaced apart from the substrate in a vertical direction;
crack detection circuit middle contact plugs disposed over the crack detection circuit lower contact pads;
crack detection circuit upper contact plugs disposed over the crack detection circuit middle contact plugs; and
crack detection circuit upper contact pads disposed over the crack detection circuit upper contact plugs,
wherein the crack detection circuit lower contact plug is connected to the crack detection pad connection buried electrode,
wherein the crack detection circuit upper contact pads electrically connect adjacent two of the crack detection circuit upper contact plugs to each other, and
wherein the crack detection circuit lower contact plug and the crack detection pad connection buried electrode contain a same metal.

9. The semiconductor device of claim 8,
wherein some of the crack detection circuit lower contact pads electrically connect adjacent two of the crack detection circuit middle contact plugs to each other, and
wherein at least one of the crack detection circuit lower contact pads is electrically connected to the crack detection circuit lower contact plug.

10. The semiconductor device of claim 8,
wherein the crack detection circuit structure further includes:
crack detection circuit lower electrodes disposed over the substrate; and
additional crack detection circuit lower contact plugs connecting the crack detection circuit lower contact pads to the crack detection circuit lower electrodes, and
wherein the crack detection circuit lower electrodes electrically connect adjacent two of the additional crack detection circuit lower contact plugs to each other.

11. The semiconductor device of claim 8,
wherein the crack detection circuit structure further includes crack detection circuit buried interconnections buried in the guard ring isolation region,
wherein the crack detection circuit buried interconnections include:
crack detection circuit buried electrodes; and
crack detection circuit buried capping layers disposed over the crack detection circuit buried electrodes,
wherein the crack detection circuit structure further includes additional crack detection circuit lower contact plugs connecting the crack detection circuit lower contact pads to the crack detection circuit buried electrodes, and
wherein the crack detection circuit buried electrodes electrically connect adjacent two of the additional crack detection circuit lower contact plugs to each other.

12. The semiconductor device of claim 8,
wherein the crack detection pad structure includes:
a crack detection pad lower contact plug;
crack detection pad lower contact pads disposed over the crack detection pad lower contact plug;
a crack detection pad middle contact plug disposed over the crack detection pad lower contact pad;
a crack detection pad upper contact plug disposed over the crack detection pad middle contact plug; and
a crack detection pad upper contact pad disposed over the crack detection pad upper contact plug,
wherein the crack detection pad lower contact plug is electrically connected to the crack detection pad connection buried electrode,
wherein the crack detection pad lower contact plug and the crack detection pad connection buried electrode contain a same metal.

13. A semiconductor device comprising:
a substrate having a chip area and a guard ring area defined by scribe lanes, the guard ring area being disposed to surround the chip area;
a guard ring structure disposed over the substrate in the guard ring area;
a test circuit structure disposed over the substrate in at least one of the scribe lanes;
a test pad structure disposed over the substrate in the chip area; and
a test pad connection part buried in the substrate to electrically connect the test circuit structure to the test pad structure across the guard ring area,
wherein the test pad connection part includes a test pad connection buried electrode and a test pad connection buried capping layer which is disposed over the test pad connection buried electrode.

14. The semiconductor device of claim 13, further comprising a cell structure disposed in the chip area,
wherein the cell structure includes:
a cell isolation region formed in the substrate to define a cell active region; and
a buried gate line buried in the substrate, the buried gate line including a buried gate electrode and a buried gate capping layer disposed over the buried gate electrode,
wherein the test pad connection buried electrode and the buried gate electrode are disposed at a same level, and
wherein the test pad connection buried capping layer and the buried gate capping layer are disposed at a same level.

15. The semiconductor device of claim 13,
wherein the guard ring structure includes:
guard ring lower electrodes disposed over the substrate;
guard ring lower plugs disposed over the guard ring lower electrodes;
guard ring upper plugs disposed over the guard ring lower plugs; and
guard ring upper pads disposed over the guard ring upper plugs,
wherein the guard ring lower electrodes electrically connect adjacent two of the guard ring lower plugs to each other, and
wherein the guard ring upper pads electrically connect adjacent two of the guard ring upper plugs to each other.

16. The semiconductor device of claim 15, further comprising a peripheral transistor structure disposed in the chip area,
wherein the peripheral transistor structure includes:
a peripheral isolation region in the substrate to define a peripheral active region; and
a peripheral gate electrode disposed over the peripheral active region, and
wherein the peripheral gate electrode and the guard ring lower plugs are disposed at a same level to have a same structure.

17. The semiconductor device of claim 15,
wherein the test pad structure includes:
a test pad lower contact plug;
a test pad lower contact pad disposed over the test pad lower contact plug;
a test pad upper contact plug disposed over the test pad lower contact pad; and
a test pad upper contact pad disposed over the test pad upper contact plug,
wherein the test pad lower contact plug is connected to the test pad connection buried electrode, and
wherein the crack detection pad lower contact plug and the crack detection pad connection buried electrode contain a same metal.

18. The semiconductor device of claim 17,
wherein the guard ring lower plugs and the test pad lower contact plugs are disposed at a same level,
wherein the guard ring upper plugs and the test pad upper contact plug are disposed at a same level, and
wherein the guard ring upper pads and the test pad upper contact pads are disposed at a same level.

19. The semiconductor device of claim 13,
wherein the test circuit structure includes:
a test circuit lower contact plug;
a test lower contact pad disposed over the test circuit lower contact plug;
a test circuit upper contact plug disposed over the test circuit lower contact pad; and
a test circuit upper contact pad disposed over the test circuit upper contact plug,
wherein the test circuit lower contact plug is electrically connected to the test pad connection buried electrode,
wherein the crack detection circuit lower contact plug and the crack detection pad connection buried electrode contain a same metal.

20. A semiconductor device comprising:
a substrate having a chip area and a guard ring area defined by scribe lanes, the guard ring area being disposed to surround the chip area;
a guard ring structure disposed over the substrate in the guard ring area;
a circuit structure disposed over the substrate in at least one of the scribe lanes or the guard ring area;
a pad structure disposed over the substrate in the chip area;
a pad connection part electrically connecting the circuit structure to the pad structure across the guard ring structure; and
a cell structure disposed in the chip area,
wherein the pad connection part includes a pad connection buried electrode buried in the substrate, and a pad connection buried capping layer disposed over the pad connection buried electrode,
wherein the cell structure includes a cell isolation region in the substrate to define a cell active region, and a buried gate line buried in the substrate,
wherein the buried gate line includes a buried gate electrode, and a buried gate capping layer disposed over the buried gate electrode,
wherein the pad connection buried electrode and the buried gate electrode are disposed at a same level, and
wherein the pad connection buried capping layer and the buried gate capping layer are disposed at a same level.
